(19) United States
(12) Patent Application Publication
(10) Pub. No.: US 2003/0194655 A1
(43) Pub. Date: Oct. 16, 2003

(54) Method for fabricating resistors on a printed circuit board

(75) Inventor: Wen-Long Jong, Taoyuan Hsien (TW)

Correspondence Address: Troxell Law Office PLLC, Suite 1404, 5205 Leesburg Pike, Falls Church, VA, 22041, US

(73) Assignee: COMPEQ MANUFACTURING COMPANY LIMITED

(21) Appl. No.: 10/119,213

(22) Filed: Apr. 10, 2002

(51) Int. Cl. G03F 7/32; G03F 7/40

(52) U.S. Cl. 430/313; 430/319; 430/328; 430/330

(57) ABSTRACT

A method for fabricating a resistor on a printed circuit board (PCB) uses a resistance film material, an exposure process, a photographic negative and a development process to fabricate a resistor on the PCB. The resistance film material has low content of dissolvent to prevent the resistor from shrinking and affecting the resistance of the resistor. The resistance film material has a fixed thickness, so that the thickness of the resistor in the PCB is easily controlled. Furthermore, the method uses an exposure and development process and the negative to from the resistor pattern on the PCB to make the length and width of the resistor pattern very accurate.

### BACKGROUND OF THE INVENTION

1. Field of the Invention

The present invention relates to a method for fabricating resistors on a printed circuit board (PCB), and more particularly to a method that provides accurate resistance of resistors on PCBs.

2. Description of Related Art

The earliest PCB only had metallic lines to connect electronic components soldered on the PCB. Semiconductor technology has developed to the extent that some passive electronic components are directly formed on PCBs to reduce the space occupied by them and to reduce the radiation interference among the passive electronic components such as resistors, capacitors, inductors, etc. Therefore, PCBs size can be reduced so PCBs can be used in very small electronic products.

Recently, conventional processes such as the mesh printed method have been developed to form passive electronic devices on PCBs. Fabricating a resistor on a PCB by the mesh printed method uses a stencil and a high resistance material to form a resistor on the PCB. The high resistance material can be a liquid graphite or polyimide material or the like. A quantity of dissolvent in the graphite or polymide material is about 40% to 60%. Therefore, the mesh printed method using a steel plate with multiple holes or a steel stencil to form the resistor on the PCB has faults such as uncontrolled overflow, deforming, occur that cause significant variations in the resistance of the resistor. For instance, the metallic lines first formed on the PCB are raised above the surface of the PCB. When the stencil is placed on the PCB, gaps exist between the metallic lines in the circuit, so the liquid resistance material flows in the gaps to make the resistor deform. However, additional gaps are formed between the metallic lines and the surface of the PCB when the stencil is placed on the PCB, and additional liquid resistance material flows into these gaps causing the resistance of the individual resistors to vary widely because of this additional resistance material. Furthermore liquid resistance material sticks to the stencil, which further changes the resistance of the resistor when the stencil is removed from the PCB.

The mesh printed method using the liquid resistance material to form resistors does not accurately control the resistor shape and has other features that affect the accuracy of the resistance. Using this method, the resistance accuracy of the resistor is about 15%.

Therefore, an objective of the present invention is to provide an improved method for fabricating resistors on PCBs to mitigate and/or obviate the aforementioned problems.

### SUMMARY OF THE INVENTION

The main objective of the present invention is to provide a method of fabricating resistors on a PCB with a consistent shape and resistance.

Other objects, advantages and novel features of the invention will become more apparent from the following detailed description when taken in conjunction with the accompanying drawings.

### BRIEF DESCRIPTION OF THE DRAWINGS

FIG. 1 is a flow chart of a first embodiment of a method for fabricating resistors on a printed circuit board (PCB) in accordance with the present invention;

FIGS. 2A to 2D are cross sectional side plan views of resistors formed by the first embodiment of the method for fabricating resistors on a printed circuit board (PCB) in FIG. 1;

FIG. 3 is a flow chart of a second embodiment of a method for fabricating resistors on a printed circuit board (PCB) in accordance with the present invention; and

FIGS. 4A to 4G are cross sectional side plan views of resistors formed by the second embodiment of the method for fabricating resistors on a printed circuit board (PCB) in FIG. 2.

### DETAILED DESCRIPTION OF THE PREFERRED EMBODIMENT

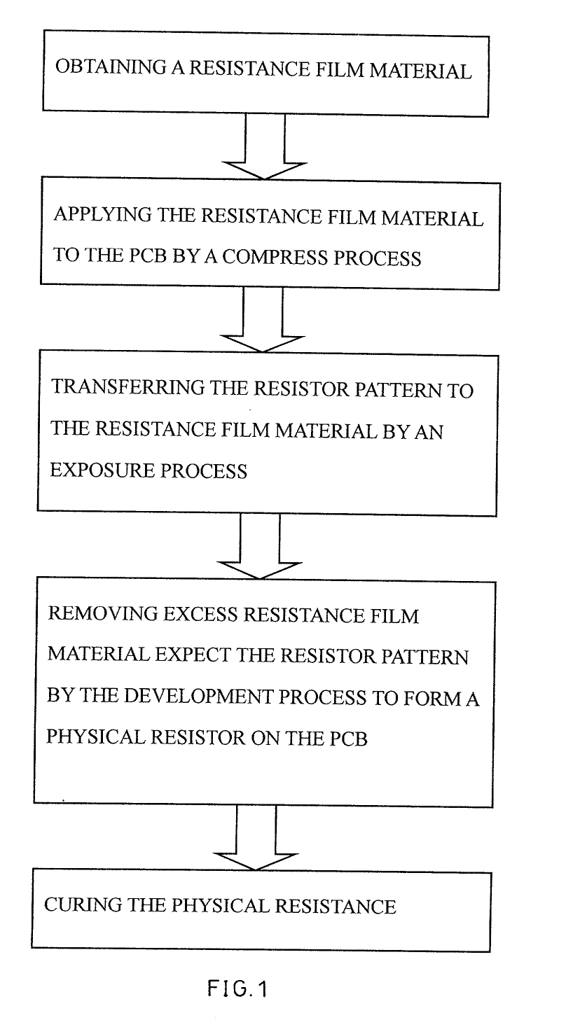

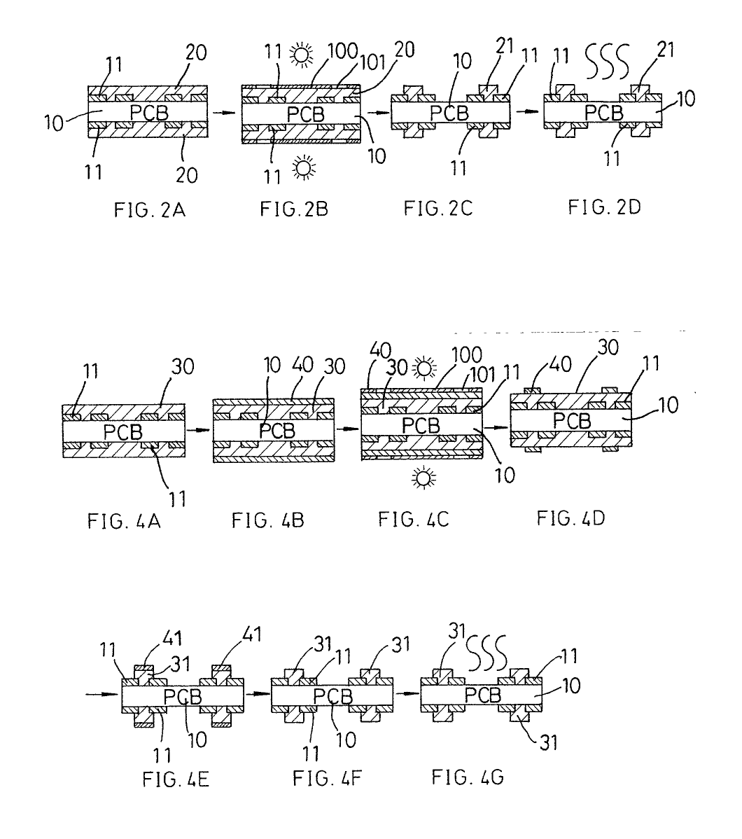

With reference to FIGS. 1 and 2, a method for fabricating a resistor (21) on a printed circuit board (PCB) (10) having two surfaces comprises steps of obtaining a resistance film material (20), applying the resistance film material (20) on at least one surface of the PCB (10) by a compress process, transferring the resistor pattern (101) to the resistance film material (20) by an exposure process, removing excess resistance film material (20) except the resistor pattern (101) by a development process to form a physical resistor (21) on the PCB (10) and curing the physical resistor (21).

In the foregoing embodiment, the resistance film material (20) is a photosensitive material such as polyamic acid or conductive material mixed with resin and metal.

With reference to FIG. 2A, the resistance film material (20) is applied to the surface of a PCB (10) having metal lines (11). The step of applying the resistance film material (20) on the surface uses a compress process such as a vacuum compress process or wet compress with N-methyl-2-pyrrolidone (NMP).

With reference to FIG. 2B, a photographic negative (100) with the resistor pattern (101) covers the resistance film material (20) to transfer the resistor pattern (101) onto the resistance film material (20) by an exposure process. The resistance film material (20) not covered by the resistor pattern (101) is polymerized by the light during the exposure process.

With reference to FIGS. 2B and 2C, when the exposure process is finished, the negative (100) is removed from the resistance film material (20) and an alkali (not shown) is put on the resistance film material (20) to remove the portion of the resistance film material (20) that has been polymerized. Therefore the remainder of the resistance film material (20) forms the physical resistor (21) on the PCB (10). With reference to FIG. 2D, a baking process or a UV light process is used to cure the physical resistor (21).

The resistance film material (20) has a fixed thickness, so the resistor (21) has a fixed thickness. Furthermore, the present method uses an exposure and development process to accurately control both the length and width. Since the resistance is determined by the equation shown, the method fabricates a resistor (21) on the PCB (11)

$$R = ( \frac{ρ}{t} ) \times \frac{L}{W}$$

with a very high accuracy. Furthermore, the resistance film material (20) is film, so the resistance film material (20) consists of a low quantity of the dissolvent (not shown). Therefore, the resistor (21) does not shrink during the curing step and avoids introducing the associated resistance errors in the resistor.

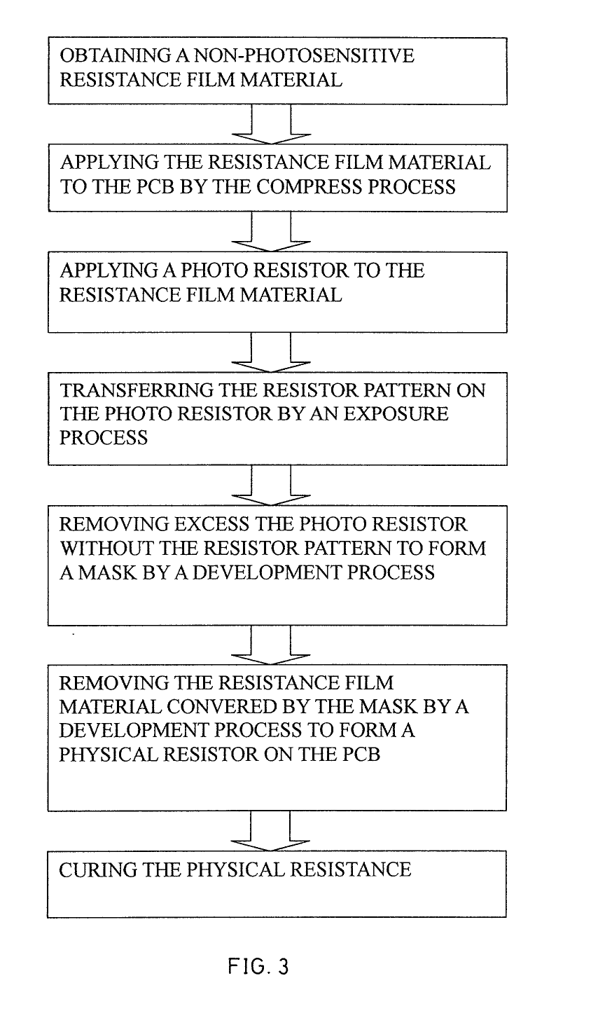

With reference to FIGS. 3 and 4, a second embodiment of the method for fabricating a resistor (31) on a printed circuit board (PCB) (10) having two surfaces with a non-photosensitive material applied to the resistance film material (30) comprises the step of obtaining a non-photosensitive resistance film material (30), applying the resistance film material (30) to at least one surface of the PCB (10) by a compress process, applying a photo resistor (40) to the resistance film material (30), transferring the resistor pattern (101) to the photo resistor (40) by an exposure process, removing excess photo resistor (40) expect the resistor pattern (101) by a development process to form a mask (41) on the resistance film material (30), removing the resistance film material not covered by the mask (41), removing the mask (41) to leave the physical resistor (31) on the PCB (10), and curing the physical resistor (31).

A difference between the first and second embodiments is using the photographic negative (40) and the non-photosensitive resistance film material (30). With reference to FIG. 4A, the non-photosensitive resistance film material (30) is compressed on the surface of the PCB (10). As shown in FIG. 4B, a photo resistor (40) is formed on the surface of the resistance film material (30) and then the photographic negative (40) with the resistor pattern (101) is placed on the photo resistor (40) before the exposure process is carried out, as shown in FIG. 4C.

With reference to FIG. 4D, after the exposure process the negative (40) is removed from the photo resistor (30), and the photo resistor (40) is polymerized with light to form a resistor pattern. The photo resistor (40) without the resistor pattern is removed to form the mask (41). Therefore, the resistance film material under the mask (41) is removed and then the mask (41) is removed to form the physical resistor (31) on the PCB, as shown FIGS. 4E and 4F

Whether the method for fabricating a resistor (31) on a printed circuit board (PCB) (10) having two surfaces uses the non-photosensitive resistance film material or not, the resistance material is a film that reduces the quantity of dissolvent in the resistance material thereby preventing the resistor from shrinking and affecting the resistance of the resistor. Furthermore, with the film, the thickness of the resistor on the PCB is virtually assured. Since the method uses an exposure and development process to from the resistor pattern on the PCB, the shape of the resistor is easy to control, too. Therefore, the thickness, the length and the width of the resistor pattern are much more accurate as is the resulting resistance.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for fabricating a resistor on a printed circuit board (PCB) with two surfaces, the method comprises the steps of:
obtaining a photosensitive resistance film material;
applying the resistance film material to the first or second surface of the PCB;
transferring a resistor pattern to the resistance film material by an exposure process;
removing the resistance film material without the resistor pattern by the development process to form a real resistor pattern; and
curing the resistor pattern on the PCB.

2. The method as claimed in claim 1, wherein the resistance film material consists of Polyamic Acid.

3. The method as claimed in claim 1, wherein the resistance film material consists of a conductive material mixed with resin and metal.

4. The method as claimed in claim 1, wherein the resistance film material is applied to the surface of the PCB by the compress process.

5. The method as claimed in claim 4, wherein the compress process is a vacuum compress process.

6. The method as claimed in claim 4, wherein the compress process is a wet compress process with N-methyl-2-pyrrolidone (NMP).

7. The method as claimed in claim 1, wherein the transferring resistor pattern step uses a photographic negative with a resistor pattern on the resistance film material to transfer the resistor pattern to the resistance film material.

8. The method as claimed in claim 1, wherein the curing the resistance pattern step is a baking process.

9. The method as claimed in claim 1, wherein the curing the resistance pattern step is a UV process.

10. A method for fabricating a resistor on a printed circuit board (PCB), with two surfaces, the method comprises the steps of:
obtaining a non-photosensitive resistance film material;
applying the resistance film material on at least one surface of the PCB by a compress process;
applying a photo resistor on the resistance film material;
transferring the resistor pattern to the photo resistor by the exposure process;
removing a portion of the photo resistor without the resistor pattern by a development process to form a mask on the resistance film material;
removing the resistance film material not covered by the mask and then removing the mask to form a physical resistor on the PCB; and
curing the physical resistor.

11. The method as claimed in claim 10, wherein the resistance film material is applied to the surface of the PCB by the compress process.

12. The method as claimed in claim 11, wherein the compress process is a vacuum compress process.

13. The method as claimed in claim 11, wherein the compress process is a wet compress process with N-methyl-2-pyrrolidone (NMP).

14. The method as claimed in claim 10, wherein the transferring resistor pattern step uses a photographic negative with a resistor pattern on the resistance film material to transfer the resistor pattern to the resistance film material.

15. The method as claimed in claim 10, wherein the curing the resistance pattern step is a baking process.

16. The method as claimed in claim 10, wherein the curing the resistance pattern step is a UV process.
